(19) United States
(12) Patent Application Publication
(10) Pub. No.: US 2010/0288348 A1
(43) Pub. Date: Nov. 18, 2010

(54) SOLAR CELL DEVICE AND METHOD FOR FABRICATING THE SAME

(75) Inventors: Chin-Ching Lin, Taichung City (TW); Mei-Ching Chiang, Taipei County (TW); Hsiang-Chuan Chen, Taoyuan County (TW); Chao-Jen Ho, Miaoli County (TW); Kuo-Chuang Chiu, Hsinchu City (TW)

Correspondence Address: QUINTERO LAW OFFICE, PC, 615 Hampton Dr, Suite A202, Venice, CA, 90291, US

(73) Assignee: Industrial Technology Research Institute, Hsinchu (TW)

(21) Appl. No.: 12/545,769

(22) Filed: Aug. 21, 2009

(30) Foreign Application Priority Data
May 13, 2009 (TW) TW98115795

(51) Int. Cl. H01L 31/0376; H01L 31/18; H01L 31/105

(52) U.S. Cl. 136/256; 438/96; 257/E21.133; 257/E31.047; 257/E31.061

(57) ABSTRACT

A solar cell device is provided, including a transparent substrate, a composite transparent conductive layer disposed over the transparent substrate, a photovoltaic element formed over the composite transparent conductive layer, and an electrode layer disposed over the photovoltaic element. In one embodiment, the composite transparent conductive layer includes a first transparent conductive layer and a second transparent conductive layer sequentially stacked over the transparent substrate, and the first transparent conductive layer is made of lithium and fluorine-codoped tin oxide and the second transparent conductive layer is made of a material selected from a group consisting of zinc oxide and titanium dioxide.

### CROSS REFERENCE TO RELATED APPLICATIONS

This application claims priority of Taiwan Patent Application No. 98115795, filed on May 13, 2009, the entirety of which is incorporated by reference herein.

### BACKGROUND OF THE INVENTION

1. Field of the Invention

The invention relates to solar cell fabrication, and in particular, to a solar cell device with transparent conductive films having improved resistances to plasma and a method for fabricating the same.

2. Description of the Related Art

Demand and application for transparent conductive films have increased, due to increased development and use of solar cell devices. In addition to solar cell devices, other examples of electronic devices using flat display panels, such as liquid crystal displays, electroluminescence panels, plasma display panels, field emission displays, and touch panels all apply transparent conductive films as electrode materials therein.

FIG. 1 is a cross section showing a transparent conductive film used in a conventional solar cell device. As shown in FIG. 1, the solar cell device is illustrated in a silicon thin film solar cell device 100, including main components such as a transparent conductive layer 104 made of fluorine doped tin oxide (FTO), an amorphous silicon thin film photovoltaic element 150 and an electrode layer 112 sequentially disposed over a glass substrate 102. Herein, the amorphous silicon thin film photovoltaic element 150 comprises components such as a p-type amorphous silicon layer, an intrinsic amorphous silicon layer 108 and an n-type amorphous silicon layer 110 sequentially stacked over the transparent conductive layer 104.

As shown in FIG. 1, the transparent conductive layer 104 made of fluorine doped tin oxide (FTO) has efficient light trapping ability. Specifically, the photovoltaic conversion rate of the amorphous silicon thin film photovoltaic element 150 for conversing the incident light 180, such as sunlight from outside of the glass substrate 102 is high. However, during fabrication of the silicon thin film solar cell device 100, the p-type amorphous silicon layer, the intrinsic amorphous silicon layer 108 and the n-type amorphous silicon layer 110 in the amorphous silicon thin film photovoltaic element 150 are typically formed by plasma enhanced chemical vapor deposition processes. Thus, due to the processes, hydrogen plasma reacts with the fluorine doped tin oxide (FTO) materials in the transparent conductive layer 104 to usually degrade conductivity and transparency thereof, after formation of a photovoltaic element 150. Should conductivity and transparency of the photovoltaic element 150 in the silicon thin film solar cell device 100 be degraded, conversion efficiency thereof would be decreased.

Therefore, a transparent conductive layer with improved resistance to plasma is needed to meet the requirements of fabricating solar cell devices which incorporate plasma related thin film processes.

### BRIEF SUMMARY OF THE INVENTION

A solar cell device and a method for fabricating the same are provided.

An exemplary solar cell device comprises a transparent substrate, a composite transparent conductive layer disposed over the transparent substrate, a photovoltaic element formed over the composite transparent conductive layer, and an electrode layer disposed over the photovoltaic element. In one embodiment, the composite transparent conductive layer comprises a first transparent conductive layer and a second transparent conductive layer sequentially stacked over the transparent substrate, and the first transparent conductive layer is made of lithium and fluorine-codoped tin oxide and the second transparent conductive layer is made of a material selected from a group consisting of zinc oxide and titanium dioxide.

An exemplar method for fabricating a solar cell device comprises providing a transparent substrate. A first transparent conductive layer is formed over the transparent substrate, wherein the first transparent conductive layer is made of lithium and fluorine-codoped tin oxide. A second transparent conductive layer is formed over the first transparent conductive layer, wherein the second transparent conductive layer is made of a material selected from a group consisting of zinc oxide and titanium dioxide. A photovoltaic element is formed over the second transparent conductive layer. An electrode layer disposed is formed over the photovoltaic element.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is cross section of a conventional solar cell device;

FIGS. 2-5 are cross sections showing a method for fabricating a solar cell device according to an embodiment of the invention;

FIG. 6 shows haze test results of solar cell devices according to an embodiment of the invention and a Comparative embodiment;

FIG. 7 shows visible-light transmittance test results of solar cell devices according to an embodiment of the invention and a Comparative embodiment;

FIG. 8 shows a sheet resistance test result of a solar cell device according to an embodiment of the invention which had been processed with hydrogen plasmas; and

FIG. 9 shows a visible light transmittance test result of a solar cell device according to an embodiment of the invention which had been processed with hydrogen plasmas.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

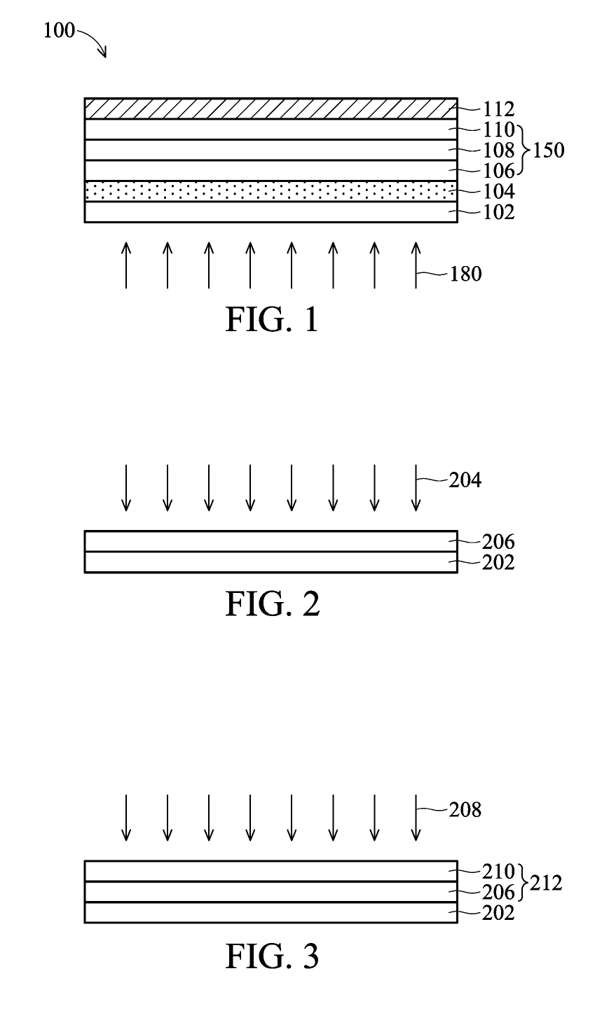

FIGS. 2-5 are cross sections showing a method for fabricating a solar cell device according to an embodiment of the invention.

As shown in FIG. 2, a transparent substrate 202, such as a glass substrate, a polymer thin film or a flexible substrate, is first provided. Next, a thin film deposition process 204 is performed to form a first transparent conductive layer 206 over the transparent substrate 202. The thin film deposition process 204 can be, for example, a chemical spraying process or an atmosphere chemical synthesizing process, and the first transparent conductive layer 206 may be formed with a material such as lithium and fluorine-codoped tin oxide (Li—F:SnO₂), having a thickness of about 10-3000 nm. In one embodiment, while the first transparent conductive layer 204 is formed by the chemical spraying process, droplets having a size of about 0.1-50 μm formed by a gaseous mixture including carrier gases such as air, oxygen, nitrogen, and reaction gases such as Sn(OH)₄, NH₄F, LiF and Li(OH) are formed under a temperature of about 200-650° C. by an atomizer having a oscillation frequency of about 1.5 KHz-2.6 Mhz or a fine nozzle having an opening of about 10 μm and provided to the heated transparent substrate 202 to thereby form the first transparent conductive layer 204.

As shown in FIG. 3, a thin film deposition process 208 is then performed to form a second transparent conductive layer 210 over the first transparent conductive layer 206 illustrated in FIG. 2. Herein, the thin film deposition process 208 can be formed by a process such as a sputtering, chemical gelling, spraying or evaporation process. The second transparent conductive layer 210 is formed with a material selected from a group consisting of zinc oxide (ZnO) and titanium dioxide (TiO₂), having a thickness of about 10-3000 nm.

Herein, the first transparent conductive layer 206 and the second transparent conductive layer 210 form a composite transparent conductive layer 212, wherein the material in the first transparent conductive layer 206 is formed with a grain size greater than that of the material in the second transparent conductive layer 210. The first transparent conductive layer 206 is therefore formed with a more rough surface and has a greater haze level for allowing more scattering of the incident lights passing through the solar cell device and the sequentially formed thin film and improving conversion efficiency of a photovoltaic element (not shown) therein. The second transparent conductive layer 210 can be further doped with elements such as Al, Ga, B, F, Li, or combinations thereof. The first transparent conductive layer 206 can be formed with a surface roughness of about, for example, not less than 15 RMS, and preferably of about 40-60 RMS, and the second transparent conductive layer 210 is formed with a surface roughness of about, for example, not more than 20 RMS, and preferably of about 8-15 RMS.

With the previously described combinations, the composite transparent conductive layer 212 can be formed with a sheet resistance not greater than 30Ω/□ and a visible-light transmittance not less than 60%. The sheet resistance of the composite transparent conductive layer 212 is preferably about 3˜15Ω/□, and the visible-light transmittance of the visible-light transmittance is preferably about 60˜70%.

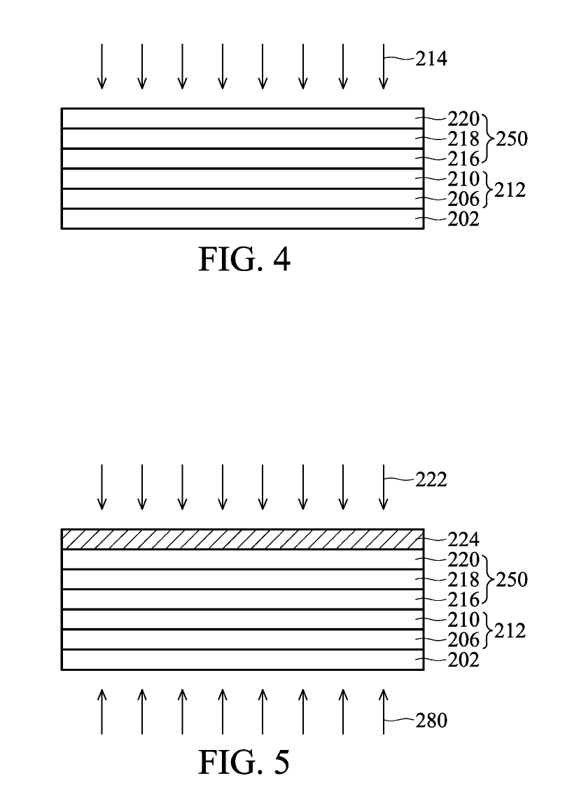

As shown in FIG. 4, a thin film deposition process 214 is performed to form a photovoltaic element 250 over the second transparent conductive layer 210 illustrated in FIG. 3. Herein, the photovoltaic element 250 is illustrated as an amorphous silicon p-i-n photovoltaic structure, but is not limited thereto. The photovoltaic element 250 can be formed as other types of photovoltaic structures such as a dye sensitized solar cell (DSSC) structure, a nanocrystalline silicon structure, or a photovoltaic element formed with a tandem structure. In the thin film deposition process 214, a p-type amorphous silicon layer 216 is first formed over the second transparent conductive layer 210, an intrinsic (non-doped) amorphous silicon layer 218 is then formed over the p-type amorphous silicon layer 216, and an n-type amorphous silicon layer 220 is then formed over the intrinsic amorphous silicon layer 218. The thin film deposition process 214 can be in-situ performed in the same processing apparatus, wherein the three films of the photovoltaic element 250 are in-situ doped with predetermined types of dopants. Therefore, no additional ion implanting process is needed, thus simplifying the fabrication process of the photovoltaic element 250. Herein, the thin film deposition process 214 can be, for example, plasma enhanced chemical vapor deposition, and the thin film deposition process 214 may use silane as a reaction gas, wherein hydrogen plasma is thus formed during the thin film deposition process 214.

As shown in FIG. 5, a thin film deposition process 222 is then performed to form an electrode layer 224 over the photovoltaic element 250 illustrated in FIG. 4 Herein, the thin film deposition process 222 can be a process such as sputtering and the electrode layer 224 may comprise materials such as Al, Ti, Mo, or Ag. As shown in FIG. 5, a substantially fabricated solar cell device 200 is shown, wherein surrounding light 280 may pass through the transparent substrate 202 and the composite transparent conductive layer 212 and arrive at the photovoltaic element 250 for photovoltaic conversion effect. In the invention, the solar cell 200 utilizes the composite transparent conductive layer 212 including the first transparent conductor layer 206 made of lithium and fluorine-codoped tin oxide and the second transparent conductive layer 210 made of a material such as zinc oxide. The lithium doped fluorine tin oxide in the first transparent conducive layer 206 shows efficient light trapping ability. Additional, the lithium and fluorine-codoped tin oxide in the first transparent conducive layer 206 can form a thin film with various surface configurations and haze levels. Meanwhile, the second transparent conductive layer 210 of zinc oxide formed over the first transparent conducive layer 206 provides high conductivity and resistance to hydrogen plasma degradation. Thus, combinations of the two material types produce a composite and highly efficient transparent conductive electrode having efficient light trapping ability, high conductivity, and high resistance to hydrogen plasma. A solar cell device using such a transparent conductive electrodes may outperform solar cell devices using conventionally formed transparent conductive electrode

### EMBODIMENTS

### Embodiment 1

### Fabrication of a Composite Transparent Conductive Layer

0.5 mole of SnCl₂.5H₂O and 0.125 mole of NH₄F were mixed and 25% of LiCl was added to and mixed with a water solution in a container. Air was simultaneously conducted in a micro type droplet atomizer, and an atomizer in the micro type droplet atomizer was adjusted to uniformly mix the Sn(OH)₄ with the air and then adjusted to a flow rate of about 20 L/min to form an aerosol airflow with a size of about 5-8 μm. Next, the aerosol airflow was directly directed to a heated glass sample to form a transparent conductive film made of mainly lithium and fluorine-codoped tin oxide by chemical deposition. The atomizer was operated under an oscillation frequency of 1000 KHz and the aerosol airflow was directly directed to the heated glass sample at a temperature of about 400° C.

0.5 mole of zinc acetate and 0.1 mole of aluminum nitride were mixed with a water solution in a container. Air was simultaneously conducted in a micro type droplet atomizer, and an atomizer in the micro type droplet atomizer was adjusted to uniformly mix Zn(OH)₂ which obtained from reaction of the zinc acetate with the water with the air and then adjusted to a flow rate of about 20 L/min to form an aerosol airflow with a size of about 5-8 μm. Next, the aerosol airflow was directly directed to a heated glass sample with the transparent conductive film made of mainly lithium and fluorine-codoped tin oxide thereover to form another transparent conductive film made of mainly aluminum zinc oxide by chemical deposition. The atomizer was operated under an oscillation frequency of 1000 KHz and the aerosol airflow was directly directed to the heated glass sample at a temperature of about 500° C. The aluminum zinc oxide thin film can be optionally deposited over the lithium doped fluorine tin oxide thin film by DC sputtering at a power of about 150 W, a pressure of about 5 mTorr, a temperature of about 200° C., and a deposition time of about 5-10 min.

### Comparative Embodiment 1

0.4 mole of SnCl₂.5H₂O and 0.125 mole of NH₄F were mixed with a water solution in a container. Air was simultaneously conducted in a micro type droplet atomizer, and an atomizer in the micro type droplet atomizer was adjusted to uniformly mix the Sn(OH)₄ with the air and then adjusted to a flow rate of about 20 L/min to form an aerosol airflow with a size of about 5-8 μm. Next, the aerosol airflow was directly directed to a heated glass sample to form a transparent conductive film made of mainly fluorine doped tin oxide by chemical deposition. The atomizer was operated under an oscillation frequency of 1000 KHz and the aerosol airflow was directly directed to the heated glass sample at a temperature of about 420° C.

### Embodiment 2

### Haze Tests

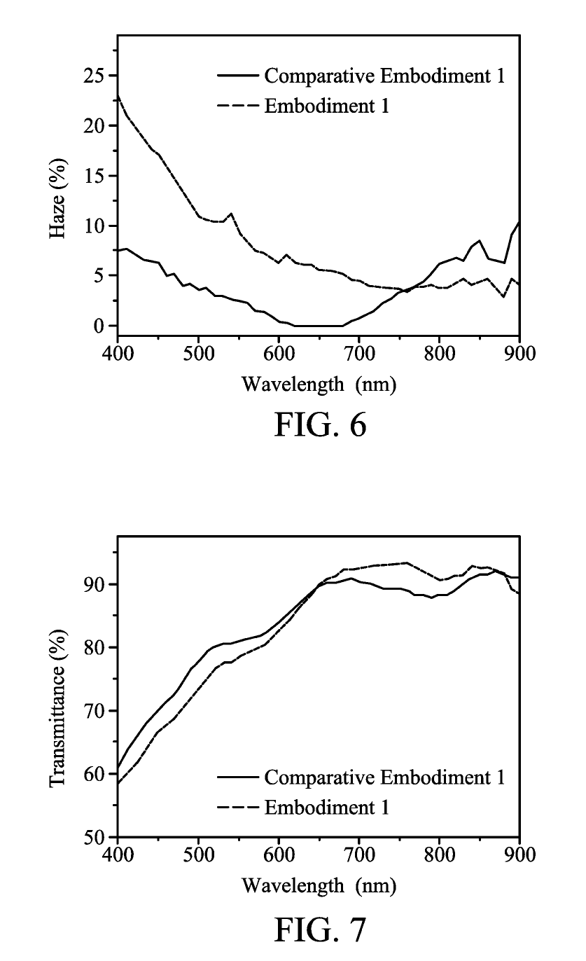

FIG. 6 shows haze test results of the transparent conductive layers provided by Embodiment 1 and Comparative Embodiment 1 according to ASTM D1003-95 measurements by using an Xenon lamp and charge-coupled device (CCD) detector with visible spectrum. It was found that in a visible light wavelength range (400-700 nm), the transparent conductive layer in Embodiment 1 showed a haze level of about four times that of the transparent conductive layer in the Comparative Embodiment 1.

### Embodiment 3

### Visible-Light Transmittance Tests

FIG. 7 shows visible-light transmittance test results of the transparent conductive layers provided by Embodiment 1 and Comparative Embodiment 1 according to ASTM C1649 measurements by using an Xenon lamp and charge-coupled device (CCD) detector with visible spectrum. It was found in a visible light wavelength range (400-700 nm), a difference of not more than 5% in visible-light transmittance existed between the transparent conductive layers in Embodiment 1 and Comparative Embodiment 1 and a visible light transmittance of 78% was seen at a wavelength of about 550 nm.

### Embodiment 4

### Hydrogen Plasma Processing Tests

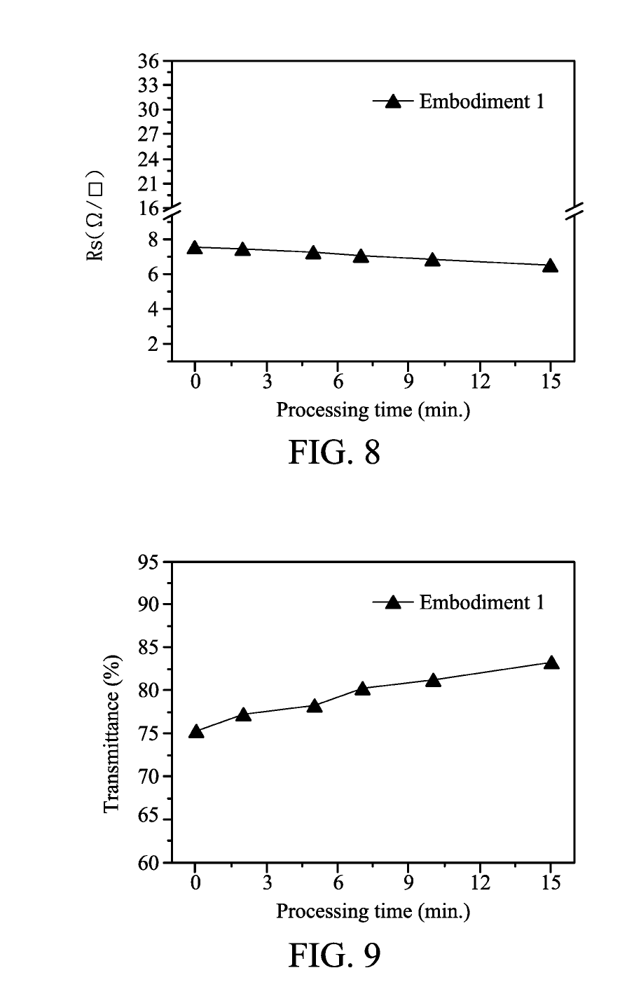

FIGS. 8 and 9 show a sheet resistance test result and a visible light transmittance test result of the transparent conductive layer in the Embodiment 1. A hydrogen plasma process was performed on the sample with the transparent conductive layer in the Embodiment 1 by utilizing a plasma enhanced chemical vapor deposition (PECVD) system conducting hydrogen gas (100%) for 1-30 minutes to treat the transparent conductive layers provided by Embodiment 1. As shown in FIG. 8, the transparent conductive layer provided by Embodiment 1 showed improved sheet resistance thereof following the plasma treatment and was not degraded, and showed a sheet resistance reduced from 7.8Ω/□ (original) to 6.7Ω/□. As shown in FIG. 9, a similar improvement was also shown in results of light transmittance tests, showing an elevated value from 75% to 80%.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell device, comprising:
a transparent substrate;
a composite transparent conductive layer disposed over the transparent substrate, wherein the composite transparent conductive layer comprises a first transparent conductive layer and a second transparent conductive layer sequentially stacked over the transparent substrate, and the first transparent conductive layer is made of lithium and fluorine-codoped tin oxide and the second transparent conductive layer is made of a material selected from a group consisting of zinc oxide and titanium dioxide;
a photovoltaic element formed over the composite transparent conductive layer; and
an electrode layer disposed over the photovoltaic element.

2. The solar cell device as claimed in claim 1, wherein the first transparent conductive layer has a grain size greater than that of the second transparent conductive layer.

3. The solar cell device as claimed in claim 1, wherein the transparent substrate is a glass substrate, a polymer thin film or a flexible substrate.

4. The solar cell device as claimed in claim 1, wherein the second transparent conductive layer is doped with Al, Ga, B, F, Li or combinations thereof.

5. The solar cell device as claimed in claim 1, wherein the first transparent conductive layer is formed with a thickness of about 10-3000 nm.

6. The solar cell device as claimed in claim 1, wherein the second transparent conductive layer is formed with a thickness of about 10-3000 nm.

7. The solar cell device as claimed in claim 1, wherein the photovoltaic element comprises a p-type amorphous silicon layer, an intrinsic amorphous silicon layer, and a b-type amorphous silicon layer.

8. The solar cell device as claimed in claim 1, wherein the electrode layer comprises Mo.

9. The solar cell device as claimed in claim 1, wherein the composite transparent conductive layer has a sheet resistance of not more than 30Ω/□.

10. The solar cell device as claimed in claim 1, wherein the composite transparent conductive layer has a visible-light transmittance of not less than 60%.

11. A method for fabricating a solar cell device, comprising:
providing a transparent substrate;
forming a first transparent conductive layer over the transparent substrate, wherein the first transparent conductive layer is made of lithium and fluorine-codoped tin oxide;
forming a second transparent conductive layer over the first transparent conductive layer, wherein the second transparent conductive layer is made of a material selected from a group consisting of zinc oxide and titanium dioxide;
forming a photovoltaic element over the second transparent conductive layer; and
forming an electrode layer disposed over the photovoltaic element.

12. The method as claimed in claim 11, wherein the first transparent conductive layer is formed by a chemical spraying process or an atmosphere chemical synthesizing process.

13. The method as claimed in claim 11, wherein the second transparent conductive layer is formed by sputtering, chemical gelling, spraying, or evaporation.

14. The method as claimed in claim 11, wherein formation the photovoltaic element over the second transparent conductive layer comprising:
forming a p-type amorphous silicon layer over the second transparent conductive layer;
forming an intrinsic amorphous silicon layer over the p-type amorphous silicon layer; and
forming an n-type amorphous silicon layer over the intrinsic amorphous silicon layer.

15. The method as claimed in claim 14, wherein the p-type amorphous silicon layer, the intrinsic amorphous silicon layer, and the n-type amorphous silicon layer are formed by plasma enhanced chemical vapor deposition.

16. The method as claimed in claim 11, wherein the first transparent conductive layer has a grain size greater than that of the second transparent conductive layer.

17. The method as claimed in claim 11, wherein the second transparent conductive layer is doped with Al, Ga, B, F, Li or combinations thereof.

18. The method as claimed in claim 11, wherein the first transparent conductive layer is formed with a thickness of about 10-3000 nm.

19. The method as claimed in claim 11, wherein the second transparent conductive layer is formed with a thickness of about 10-3000 nm.

20. The method as claimed in claim 11, wherein the electrode layer comprises Mo.
